(19) United States
(12) Patent Application Publication
(10) Pub. No.: US 2023/0307230 A1
(43) Pub. Date: Sep. 28, 2023

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventors: Takashi NAKAGAWA, Toyama-shi (JP); Shinya SASAKI, Toyama-shi (JP); Noriaki MICHITA, Toyama-shi (JP); Katsuhiko YAMAMOTO, Toyama-shi (JP)

(73) Assignee: Kokusai Electric Corporation, Tokyo (JP)

(21) Appl. No.: 18/186,699

(22) Filed: Mar. 20, 2023

(30) Foreign Application Priority Data
Mar. 24, 2022 (JP) 2022-048244

(51) Int. Cl. H01L 21/02; H01L 21/324; H01L 21/67

(52) U.S. Cl. CPC H01L 21/02356; H01L 21/324; H01L 21/67115; H01L 21/67103

(57) ABSTRACT

There is provided a technique that includes: loading a substrate in which a treatment target film and an action target film are formed into a process chamber; irradiating the action target film with an electromagnetic wave; and causing the action target film to generate heat by the irradiation with the electromagnetic wave and modifying the treatment target film with a directionality by heating the treatment target film with the heat generated by the action target film.

### CROSS-REFERENCE TO RELATED APPLICATION

This application is based upon and claims the benefit of priority from Japanese Patent Application No. 2022-048244, filed on Mar. 24, 2022, the entire contents of which are incorporated herein by reference.

### TECHNICAL FIELD

The present disclosure relates to a method of processing a substrate, a method of manufacturing a semiconductor device, a recording medium, and a substrate processing apparatus.

### BACKGROUND

As a process of manufacturing a semiconductor device, for example, there is a modification treatment represented by an annealing treatment of heating a substrate in a process chamber by using a heater to change a composition and a crystal structure in a thin film formed on a surface of the substrate or repair crystal defects and the like in the filmed thin film. In recent years, semiconductor devices have become remarkably miniaturized and highly integrated, and along with this, there is a demand for modification treatment for a high-density substrate in which a pattern with a high aspect ratio is formed. In the related art, a heat treatment method in which microwaves are used are studied as a method of modifying such a high-density substrate.

In the related-art treatment where the microwaves are used, some films may be affected by thermal history depending on films formed on the substrate, and it may be difficult to uniformly process (modify) a film formed on the substrate at a low temperature while satisfying the thermal history demanded in a device manufacturing process.

### SUMMARY

Some embodiments of the present disclosure provide a technique capable of uniformly processing a film formed on a substrate while lowering a temperature of the substrate.

According to some embodiments of the present disclosure, there is provided a technique that includes: loading a substrate in which a treatment target film and an action target film are formed into a process chamber; irradiating the action target film with an electromagnetic wave; and causing the action target film to generate heat by the irradiation with the electromagnetic wave and modifying the treatment target film with a directionality by heating the treatment target film with the heat generated by the action target film.

### BRIEF DESCRIPTION OF DRAWINGS

The accompanying drawings, which are incorporated in and constitute a part of the specification, illustrate embodiments of the present disclosure.

FIG. 1 is a longitudinal sectional view showing a schematic structure of a substrate processing apparatus suitably used in embodiments of the present disclosure.

FIG. 2 is a cross-sectional view showing a schematic structure of a substrate processing apparatus suitably used in embodiments of the present disclosure.

FIG. 3 is a view showing a schematic structure of a single-wafer process furnace of a substrate processing apparatus suitably used in embodiments of the present disclosure, in which a portion of the process furnace is shown in a longitudinal sectional view.

FIG. 4 is a view showing a schematic structure of a controller of a substrate processing apparatus suitably used in the present disclosure.

FIG. 5 is a diagram showing a flow of substrate processing in the present disclosure.

FIG. 6A is a cross-sectional view schematically showing a structure of a film on a substrate, which is suitably used in embodiments of the present disclosure. FIG. 6B is a cross-sectional view schematically showing a structure of a film on a substrate after the substrate shown in FIG. 6A is subjected to a modification treatment according to the present disclosure.

FIG. 7A is a cross-sectional view schematically showing a structure of a film on a substrate in a comparative example. FIG. 7B is a cross-sectional view schematically showing a structure of a film on a substrate after the substrate shown in FIG. 7A is subjected to the modification treatment according to the present disclosure.

FIG. 8 is a diagram showing comparison of a refractive index of an amorphous Si film after modification treatment in first to third comparative Examples with a refractive index of an amorphous Si film after modification treatment in the embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Some embodiments of the present disclosure will now be described with reference to the drawings. The drawings used in the following description are schematic, and dimensional relationships, ratios, and the like of various components shown in the drawing may not match actual ones. Further, dimensional relationship, ratios, and the like of various components among plural drawings may not match one another.

### (1) Structure of Substrate Processing Apparatus

In the embodiments, a substrate processing apparatus 100 according to the present disclosure is configured as a single-wafer heat treatment apparatus that performs various heat treatments on a wafer, and will be described with an apparatus that performs annealing treatment (modification treatment) in which electromagnetic waves are used, which will be described later. In the substrate processing apparatus 100 of the embodiments of the present disclosure, a FOUP (Front Opening Unified Pod: hereinafter referred to as a pod) 110 is used as a storage container (carrier) in which a wafer 200 as a substrate is accommodated. The pod 110 is also used as a transfer container configured to transfer the wafer 200 among various substrate processing apparatuses.

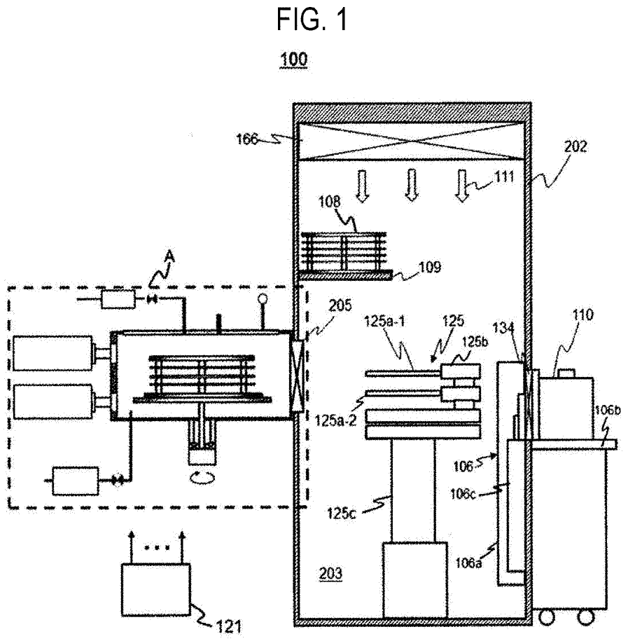

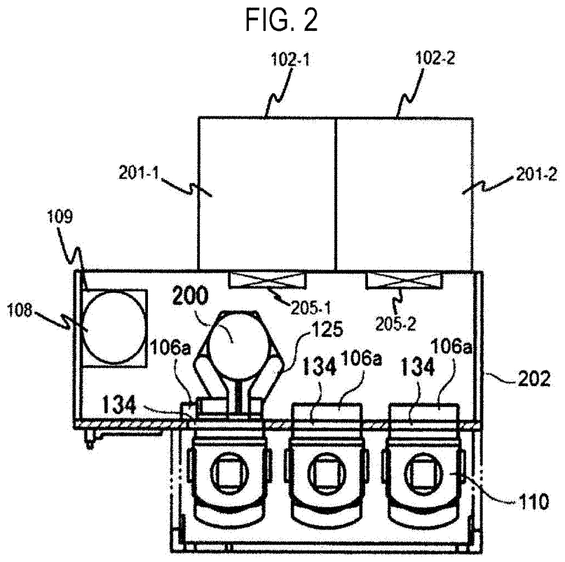

As shown in FIGS. 1 and 2, the substrate processing apparatus 100 includes a transfer housing (housing) 202 including therein a transfer chamber (transfer area) 203 configured to transfer the wafer 200, and cases 102-1 and 102-2, which serve as process containers to be described later, that are installed at a sidewall of the transfer housing 202 and include therein process chambers 201-1 and 201-2 configured to process the wafer 200, respectively. A load port unit (LP) 106 as a pod opening/closing mechanism configured to open/close a lid of the pod 110 and load/unload the wafer 200 into/from the transfer chamber 203 is arranged on the right side of FIG. 1 (the lower side of FIG. 2) which is the front side of the housing of the transfer chamber 203. The load port unit 106 includes a housing 106a, a stage 106b, and an opener 106c. The stage 106b is configured to mount the pod 110 and is configured to bring the pod 110 close to a substrate loading/unloading port 134 formed in front of the housing of the transfer chamber 203. The opener 106c opens/closes a lid (not shown) installed at the pod 110. Further, the housing 202 includes a purge gas circulation structure including a clean unit 166 configured to circulate a purge gas such as N₂ in the transfer chamber 203.

Gate valves 205-1 and 205-2 that open/close the process chambers 201-1 and 202-2, respectively, are arranged on the left side of FIG. 1 (the upper side of FIG. 2) which is the rear side of the housing 202 of the transfer chamber 203. A transfer machine 125 as a substrate transfer mechanism (substrate transfer robot) configured to transfer the wafer 200 is installed at the transfer chamber 203. The transfer machine 125 includes tweezers (arms) 125a-1 and 125a-2 as mounters configured to mount the wafer 200, a transfer apparatus 125b that may rotate or linearly move each of the tweezers 125a-1 and 125a-2 in the horizontal direction, and a transfer apparatus elevator 125c that raises or lowers the transfer apparatus 125b. By continuous operation of the tweezers 125a-1 and 125a-2, the transfer apparatus 125b, and the transfer apparatus elevator 125c, the wafer 200 may be loaded (charged) or unloaded (discharged) into or from a substrate holder (boat) 217, which will be described later, or the pod 110. Hereinafter, the cases 102-1 and 102-2, the process chambers 201-1 and 201-2, and the tweezers 125a-1 and 125a-2 will be simply referred to as a case 102, a process chamber 201, and a tweezers 125a, respectively, in a case where they may not be distinguished from each other.

As shown in FIG. 1, in a space above the transfer chamber 203 and below the clean unit 166, a wafer cooling mounting tool 108 configured to cool the processed wafer 200 is installed on a wafer cooling table 109. The wafer cooling mounting tool 108 is formed in a structure similar to that of the boat 217 as the substrate holder to be described later and is configured to be capable of holding a plurality of wafers 200 horizontally in multiple vertical stages by a plurality of wafer holding grooves (holders). By installing the wafer cooling mounting tool 108 and the wafer cooling table 109 above installation positions of the substrate loading/unloading port 134 and the gate valve 205, they are out of a motion line when the wafer 200 is transferred from the pod 110 to the process chamber 201 by the transfer machine 125, thereby making it possible to cool the processed wafer 200 without lowering a wafer processing throughput. Hereinafter, the wafer cooling mounting tool 108 and the wafer cooling table 109 may be collectively referred to as a cooling area.

Here, an internal pressure of the pod 110, an internal pressure of the transfer chamber 203, and an internal pressure of the process chamber 201 are controlled to be the atmospheric pressure or a pressure higher by about 10 to 200 Pa (gauge pressure) than the atmospheric pressure. The internal pressure of the transfer chamber 203 may be higher than the internal pressure of the process chamber 201, and the internal pressure of the process chamber 201 may be higher than the internal pressure of the pod 110.

### (Process Furnace)

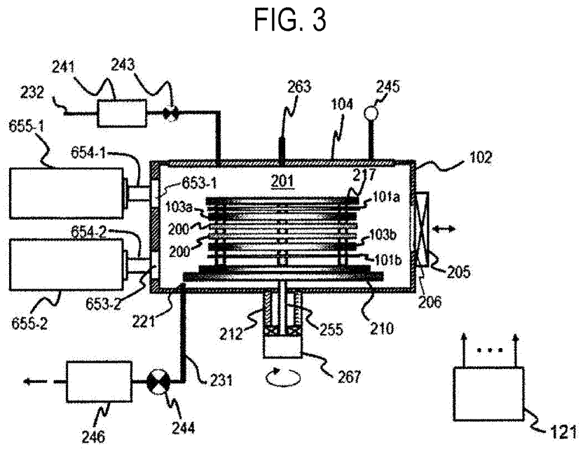

A process furnace with a substrate processing structure as shown in FIG. 3 is formed in a region A surrounded by a broken line in FIG. 1. In the embodiments of the present disclosure, a plurality of process furnaces are provided as shown in FIG. 2, but since structures of the process furnaces are the same, a structure of one process furnace will be described and structures of other process furnaces will not be described.

As shown in FIG. 3, the process furnace includes the case 102 as a cavity (process container) made of material that reflects electromagnetic waves, such as metal. Further, on a ceiling surface of the case 102, a cap flange (closing plate) 104 made of metal material is configured to close the ceiling surface of the case 102 via an O-ring (not shown) as a seal. The inner space of the case 102 and the cap flange 104 mainly constitutes the process chamber 201 configured to process a substrate such as a silicon wafer. A reaction tube (not shown) made of quartz through which electromagnetic waves may pass may be installed inside the case 102, or a process container may be configured so that the interior of the reaction tube serves as a process chamber. Further, the process chamber 201 may be formed by using the case 102 with its ceiling closed, without installing the cap flange 104.

A mounting stage 210 is installed in the process chamber 201, and the boat 217 as the substrate holder configured to hold the wafer 200 as the substrate is mounted on the upper surface of the mounting stage 210. The boat 217 holds the wafer 200 to be processed and quartz plates 101a and 101b as heat insulating plates placed vertically above and below the wafer 200 to sandwich the wafer 200 at predetermined intervals. Further, susceptors 103a and 103b such as a silicon plate (Si plate) and a silicon carbide plate (SiC plate) may be placed between the quartz plates 101a and 101b and the wafer 200, respectively. In the embodiments of the present disclosure, the quartz plates 101a and 101b and the susceptors 103a and 103b are the same components, respectively, and they will be referred to as a quartz plate 101 and a susceptor 103 respectively in a case where they may not be distinguished from each other.

The case 102 as the process container is formed with, for example, a circular cross section and is formed as a flat closed container. Further, the transfer housing 202 is made of, for example, metal material such as aluminum (Al) or stainless steel (SUS). A space surrounded by the case 102 may be referred to as the process chamber 201 or a reaction area 201 as a process space, and a space surrounded by the transfer housing 202 may be referred to as the transfer chamber 203 or the transfer area 203 as a transfer space. Further, the process chamber 201 and the transfer chamber 203 are not limited to being configured to be adjacent to each other in the horizontal direction as in the embodiments of the present disclosure, but may be configured to be adjacent to each other in the vertical direction.

As shown in FIGS. 1, 2, and 3, a substrate loading/unloading port 206, which is adjacent to the gate valve 205, is installed at the side surface of the transfer housing 202, and the wafer 200 moves between the process chamber 201 and the transfer chamber 203 via the substrate loading/unloading port 206.

An electromagnetic wave supplier as a heater, which will be described in detail later, is installed at the side surface of the case 102, and an electromagnetic wave such as microwaves supplied from the electromagnetic wave supplier is introduced into the process chamber 201 to heat the wafer 200 and the like, thus processing the wafer 200.

The mounting stage 210 is supported by a shaft 255 as a rotary shaft. The shaft 255 penetrates a bottom of the case 102, and is further connected to a driver 267 that performs a rotation operation outside the transfer container 202. By operating the driver 267 to rotate the shaft 255 and the mounting stage 210, it is possible to rotate the wafer 200 placed on the boat 217. Further, the circumference of the lower end portion of the shaft 255 is covered with a bellows 212 to keep the inside of the process chamber 201 and the transfer area 203 airtight.

Here, the mounting stage 210 may be configured to be raised or lowered by the driver 267 depending on a height of the substrate loading/unloading port 206 so that the wafer 200 is at a wafer transfer position when the wafer 200 is transferred, and the wafer 200 is at a processing position (wafer processing position) in the process chamber 201 when the wafer 200 is processed.

An exhauster configured to exhaust the atmosphere of the process chamber 201 is installed below the process chamber 201 and on the outer peripheral side of the mounting stage 210. As shown in FIG. 3, an exhaust port 221 is provided at the exhauster. An exhaust pipe 231 is connected to the exhaust port 221, and a pressure regulator 244 such as an APC valve that controls an opening state of the valve according to the internal pressure of the process chamber 201 and a vacuum pump 246 are sequentially connected in series to the exhaust pipe 231.

Here, the pressure regulator 244 is not limited to the APC valve but may be configured to be used together with a normal opening/closing valve and a normal pressure regulating valve, as long as it may receive pressure information (a feedback signal from a pressure sensor 245 to be described later) in the process chamber 201 and regulate an exhaust amount.

The exhauster (also referred to as an exhaust system or an exhaust line) mainly includes the exhaust port 221, the exhaust pipe 231, and the pressure regulator 244. The exhaust port may be installed to surround the mounting stage 210 such that a gas may be exhausted from the entire circumference of the wafer 200. Further, the vacuum pump 246 may be included in the exhauster.

The cap flange 104 is provided with a gas supply pipe 232 configured to supply process gases for various substrate processing, such as an inert gas, a precursor gas, and a reaction gas, into the process chamber 201.

The gas supply pipe 232 is provided with a mass flow controller (MFC) 241, which is a flow rate controller (flow rate control part), and a valve 243, which is an opening/closing valve, sequentially from the upstream side of the gas supply pipe 232. For example, a source of nitrogen (N₂) gas, which is an inert gas, is connected to the upstream side of the gas supply pipe 232 to supply the nitrogen gas into the process chamber 201 via the MFC 241 and the valve 243. When a plurality of kinds of gases are used when processing the substrate, the plurality of kinds of gases may be supplied by using a structure in which a gas supply pipe provided with a MFC, which is a flow rate controller, and a valve, which is an opening/closing valve sequentially from the upstream side thereof, is connected to the gas supply pipe 232 at the downstream side of the valve 243. Further, a gas supply pipe provided with a MFC and a valve may be installed for each gas type.

A gas supply system (gas supplier) mainly includes the gas supply pipe 232, the MFC 241, and the valve 243. When an inert gas flows through the gas supply system, the gas supply system is also referred to as an inert gas supply system. As the inert gas, in addition to the N₂ gas, for example, a rare gas such as an Ar gas, a He gas, a Ne gas, or a Xe gas may be used.

A temperature sensor 263, which is a non-contact temperature measuring apparatus, is installed at the cap flange 104. By regulating an output of a microwave oscillator 655, which will be described later, based on temperature information detected by the temperature sensor 263, the substrate is heated such that a temperature distribution of the substrate becomes a desired temperature distribution. The temperature sensor 263 includes a radiation thermometer such as an IR (Infrared Radiation) sensor. The temperature sensor 263 is installed to measure a surface temperature of the quartz plate 101a or a surface temperature of the wafer 200. In a case where the above-mentioned susceptor is provided, the temperature sensor 263 may be configured to measure a surface temperature of the susceptor.

When the temperature of the wafer 200 (wafer temperature) is described in the present disclosure, it will be described as referring to a case where it means a wafer temperature converted by temperature conversion data to be described later, that is, an estimated wafer temperature, a case where it means a temperature obtained by directly measuring the temperature of the wafer 200 with the temperature sensor 263, and a case where it means both of them.

By acquiring a transition of temperature change for each of the quartz plate 101 or the susceptor 103 and the wafer 200 in advance by the temperature sensor 263, temperature conversion data showing a correlation between the temperature of the quartz plate 101 or the susceptor 103 and the temperature of the wafer 200 may be stored in a memory 121c or an external memory 123. By creating the temperature conversion data in advance in this way, the temperature of the wafer 200 may be estimated by measuring the temperature of the quartz plate 101, and it is possible to control the output of the microwave oscillator 655, that is, control the heater, based on the estimated temperature of the wafer 200.

The present disclosure is not limited to the above-mentioned radiation thermometer to measure the temperature of the wafer 200. The temperature of the wafer 200 may be measured by using a thermocouple or a combination of a thermocouple and a non-contact thermometer. However, when the temperature is measured by using the thermocouple, the thermocouple may be arranged in the vicinity of the wafer 200 to measure the temperature. That is, since the thermocouple may be arranged in the process chamber 201, the thermocouple itself may be heated by the microwaves supplied from the microwave oscillator to be described later, such that the temperature may not be accurately measured. Therefore, a non-contact thermometer may be used as the temperature sensor 263.

Further, the temperature sensor 263 is not limited to being installed at the cap flange 104, but may be installed at the mounting stage 210. Further, the temperature sensor 263 may be configured to indirectly measure the temperature by reflecting a light radiating from a measurement window installed at the cap flange 104 or the mounting stage 210 with a mirror or the like, as well as may be directly installed at the cap flange 104 or the mounting stage 210. Further, the number of temperature sensors 263 is not limited to one, and a plurality of temperature sensors 263 may be installed.

Electromagnetic wave introduction ports 653-1 and 653-2 are installed at the sidewall of the case 102. One ends of waveguides 654-1 and 654-2 configured to supply electromagnetic waves into the process chamber 201 are connected to the electromagnetic wave introduction ports 653-1 and 653-2, respectively. Microwave oscillators (electromagnetic wave sources) 655-1 and 655-2 as electromagnetic wave oscillators serving as heating sources configured to supply electromagnetic waves into the process chamber 201 to perform a heating are connected to the other ends of the waveguides 654-1 and 654-2, respectively. The microwave oscillators 655-1 and 655-2 supply the electromagnetic waves such as microwaves to the waveguides 654-1 and 654-2, respectively. A magnetron, a klystrons, and the like are used as the microwave oscillators 655-1 and 655-2. Hereinafter, the electromagnetic wave introduction ports 653-1 and 653-2, the waveguides 654-1 and 654-2, and the microwave oscillators 655-1 and 655-2 will be described as an electromagnetic wave introduction port 653, a waveguide 654, and a microwave oscillator 655, respectively, when they may not be distinguished from each other.

A frequency of an electromagnetic wave generated by the microwave oscillator 655 may be controlled to fall within a frequency range of 13.56 MHz or more and 24.125 GHz or less. Further, the frequency may be controlled to 2.45 GHz or 5.8 GHz.

Here, the frequencies of the microwave oscillators 655-1 and 655-2 may be the same frequency or may be different frequencies.

Further, it is described in the embodiments of the present disclosure that two microwave oscillators 655 are arranged at a side surface of the case 102. However, the present disclosure is not limited thereto, and one or more microwave oscillators may be arranged at the side surface of the case 102. Further, the microwave oscillators may be arranged at different side surfaces such as opposite side surfaces of the case 102. The electromagnetic wave supplier (also referred to as an electromagnetic wave supplier, a microwave supplier, or a microwave supplier) as a heater mainly includes the microwave oscillators 655-1 and 655-2, the waveguides 654-1 and 654-2, and the electromagnetic wave introduction ports 653-1 and 653-2.

A controller 121, which will be described later, is connected to each of the microwave oscillators 655-1 and 655-2. The temperature sensor 263 configured to measure the temperature of the quartz plate 101a or 101b or the wafer 200 accommodated in the process chamber 201 is connected to the controller 121. The temperature sensor 263 measures the temperature of the quartz plate 101 or the susceptor 103, or the temperature of the wafer 200 by the above-described method and transmits the measured temperature to the controller 121, and the controller 121 controls the outputs of the microwave oscillators 655-1 and 655-2 to control the heating of the wafer 200.

Here, the microwave oscillators 655-1 and 655-2 are controlled by the same control signal transmitted from the controller 121. However, the present disclosure is not limited thereto, and the microwave oscillators 655-1 and 655-2 may be individually controlled by transmitting individual control signals from the controller 121 to the microwave oscillators 655-1 and 655-2, respectively.

### (Controller)

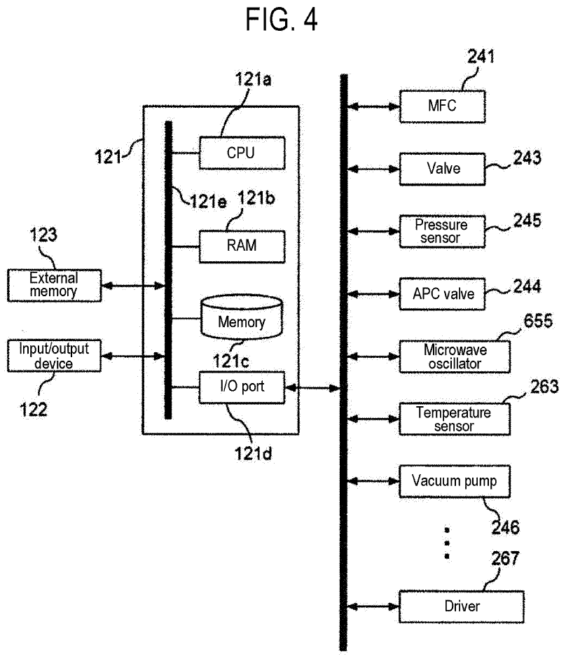

As shown in FIG. 4, the controller 121, which is a control part (control device or control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 including, e.g., a touch panel or the like, is connected to the controller 121.

The memory 121c includes, for example, a flash memory, a hard disk drive (HDD), or the like. A control program that controls operations of a substrate processing apparatus, a process recipe in which sequences and conditions of annealing (modification) treatment are written, etc. are readably stored in the memory 121c. The process recipe functions as a program configured to cause the controller 121 to execute each sequence in the substrate processing process, which will be described later, to obtain a predetermined result. Hereinafter, the process recipe and the control program may be generally and simply referred to as a “program.” Furthermore, the process recipe may be simply referred to as a “recipe.” When the term “program” is used herein, it may indicate a case of including the recipe, a case of including the control program, or a case of including both the recipe and the control program. The RAM 121b is constituted as a memory area (work area) in which programs or data read by the CPU 121a are temporarily stored.

The I/O port 121d is connected to the MFC 241, the valve 243, the pressure sensor 245, the APC valve 244, the vacuum pump 246, the temperature sensor 263, the driver 267, the microwave oscillator 655, and so on.

The CPU 121a is configured to be capable of reading and executing the control program from the memory 121c. The CPU 121a is also configured to be capable of reading the recipe from the memory 121c according to an input of an operation command from the input/output device 122. The CPU 121a is configured to be capable of controlling the flow rate regulating operation of various kinds of gases by the MFC 241, the opening/closing operation of the valve 243, the pressure regulating operation performed by the APC valve 244 based on the pressure sensor 245, the actuating and stopping operation of the vacuum pump 246, the output regulating operation performed by the microwave oscillator 655 based on the temperature sensor 263, the operation of rotating the mounting stage 210 (or the boat 217) and adjusting the rotation speed of the mounting stage 210 with the driver 267 or the operation of raising/lowering the mounting stage 210, and so on, according to contents of the read recipe.

The controller 121 may be configured by installing, on the computer, the aforementioned program stored in the external memory (for example, a magnetic disk such as a hard disk, an optical disc such as a CD, a magneto-optical disc such as a MO, or a semiconductor memory such as a USB memory or a SSD) 123. The memory 121c or the external memory 123 is configured as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Furthermore, the program may be provided to the computer by using communication means or unit such as the Internet or a dedicated line, instead of using the external memory 123.

### (2) Substrate Processing Process

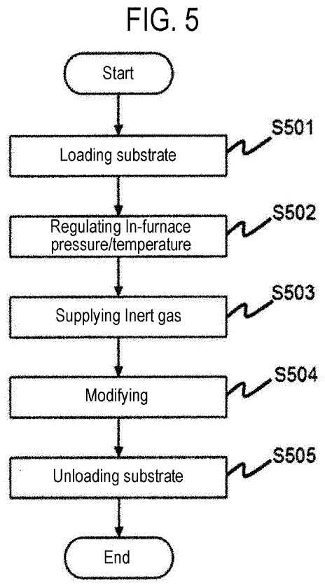

Next, by using the process furnace of the above-described substrate processing apparatus 100, as a process of manufacturing a semiconductor device, an example of a method of modifying (crystallizing) an amorphous silicon (Si) film 2002 as a film (treatment target film or target film), which is a target of heat treatment (modification treatment), formed on a wafer 200 will be described along with a process flow shown in FIG. 5. As the amorphous Si film 2002, for example, a phosphorus (P)-containing (P-added) Si film, for example, a P-containing silicon film, may be used.

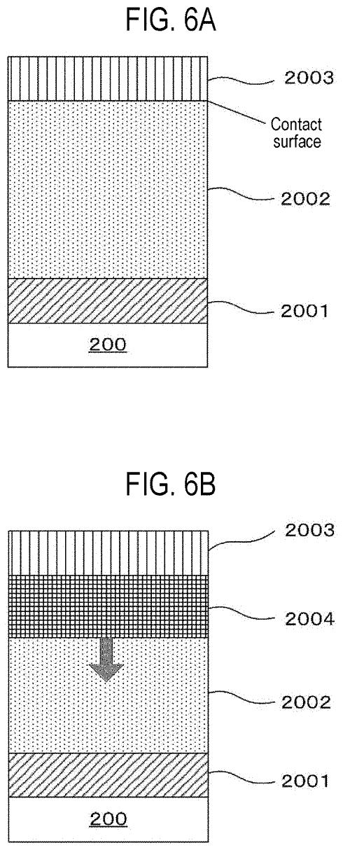

As shown in FIG. 6A, a silicon oxide film (SiO film) 2001 and an amorphous Si film 2002, which is the treatment target film, are formed on the wafer 200. Further, as a film (assist film or action target film) that assists heating of a film (treatment target film or target film) which is the target of this heat treatment (modification treatment), a metal-containing film 2003 containing metal is formed on the surface of this amorphous Si film 2002. That is, the metal-containing film 2003 is formed to cover the surface of the amorphous Si film 2002. In other words, the amorphous Si film 2002 and the metal-containing film 2003 are provided to be in contact with each other, and the metal-containing film 2003 is formed adjacent to the amorphous Si film 2002. As the metal-containing film 2003, for example, a film containing titanium (Ti) or nickel (Ni), such as a titanium nitride (TiN) film, may be used.

The SiO film 2001 is a film formed by diffusing oxygen (O) on the surface of a silicon substrate with an oxygen atmosphere set in a reaction chamber with a predetermined temperature (for example, 900 degrees C.). Further, in a case where the amorphous Si film 2002 is a P-containing Si film, it is a film formed by supplying, for example, SiH₄ (monosilane) and PH₃ (phosphine) into the reaction chamber with a predetermined temperature (for example, 500 degrees C. to 650 degrees C.). Further, the metal-containing film 2003 is a film formed by supplying a metal-containing gas into the reaction chamber with a predetermined temperature. For example, in a case where the metal-containing film 2003 is a TiN film, it is a film formed by supplying, for example, TiCl₄ (titanium tetrachloride) and NH₃ (ammonia) into the reaction chamber with a predetermined temperature (for example, 300 degrees C. to 500 degrees C.). The SiO film 2001, the amorphous Si film 2002, and the metal-containing film 2003 are formed on the wafer 200 in a substrate processing apparatus, for example, a batch-type substrate processing apparatus, different from the above-described substrate processing apparatus 100.

In the following description, the operation of each component constituting the substrate processing apparatus 100 is controlled by the controller 121. Further, as in the above-described process furnace structure, since the same processing content, that is, the same recipe is used in a plurality of process furnaces in the substrate processing process in the embodiments of the present disclosure, a substrate processing process in which one of the process furnaces is used will be described, and the substrate processing processes in which other process furnaces are used will not be described.

When the term “wafer” is used in the present disclosure, it may refer to “a wafer itself” or “a wafer and a stacked body of certain layers or films formed on a surface of the wafer.” When the phrase “a surface of a wafer” is used in the present disclosure, it may refer to “a surface of a wafer itself” or “a surface of a certain layer formed on a wafer.” When the expression “a certain layer is formed on a wafer” is used in the present disclosure, it may mean that “a certain layer is formed directly on a surface of a wafer itself” or that “a certain layer is formed on a layer formed on a wafer.” When the term “substrate” is used in the present disclosure, it may be synonymous with the term “wafer.”

### (Substrate Loading Step (S501))

As shown in FIG. 3, the wafer 200 placed on one or both of the tweezers 125a-1 and 125a-2 is loaded into a predetermined process chamber 201 by the opening/closing operation of the gate valve 205 (S501). That is, the wafer 200 formed thereon with the SiO film 2001, the amorphous Si film 2002, and the metal-containing film 2003 is loaded into the process chamber 201.

### (In-Furnace Pressure/Temperature Regulating Step (S502))

When the loading of the wafer 200 into the process chamber 201 is completed, the internal atmosphere of the process chamber 201 is controlled such that the internal pressure of the process chamber 201 becomes a predetermined pressure (for example, 10 to 102,000 Pa). Specifically, while exhausting the interior of the process chamber 201 by the vacuum pump 246, the valve opening state of the pressure regulator 244 is feedback-controlled based on the pressure information detected by the pressure sensor 245, such that the internal pressure of the process chamber 201 is set to the predetermined pressure. At the same time, the electromagnetic wave supplier may be controlled with preheating to control the heating to a predetermined temperature (S502). When the temperature is raised to a predetermined substrate processing temperature by the electromagnetic wave supplier, the temperature may be raised with an output smaller than an output of a modifying step, which will be described later, such that the wafer 200 is not deformed or damaged. Further, when the substrate processing is performed under the atmospheric pressure, the process may be controlled to proceed to an inert gas supplying step S503, which will be described later, after regulating the in-furnace temperature without regulating the in-furnace pressure.

### (Inert Gas Supplying Step (S503))

When the internal pressure and the internal temperature of the process chamber 201 are controlled to predetermined values by the in-furnace pressure/temperature regulating step S502, the driver 267 rotates the shaft 255 to rotate the wafer 200 via the boat 217 on the mounting stage 210. At this time, an inert gas such as a nitrogen gas is supplied via the gas supply pipe 232 (S503). Further, at this time, the internal pressure of the process chamber 201 is a predetermined value in a range of 10 Pa or more and 102,000 Pa or less and is regulated to be, for example, 101,300 Pa or more and 101,650 Pa or less. The shaft may be rotated during the substrate loading step S501, that is, after the wafer 200 is loaded into the process chamber 201.

### (Modifying Step (S504))

When the interior of the process chamber 201 is maintained at the predetermined pressure, the microwave oscillator 655 supplies microwaves into the process chamber 201 for a predetermined time (heating time or processing time), for example, for 600 seconds, via the above-described components. When the microwaves are supplied into the process chamber 201, the metal-containing film 2003 is irradiated and heated with the microwaves. That is, the metal-containing film 2003 is irradiated with the microwaves to generate heat, and the adjacent amorphous Si film 2002 is heated.

Here, when the metal-containing film 2003 generates heat due to the microwave irradiation, since an atom-to-atom distance (also referred to as a crystal lattice distance) in the amorphous Si film 2002 at an interface with the metal-containing film 2003 approximates an atom-to-atom distance in the metal-containing film 2003, the amorphous Si film 2002 is crystallized with being aligned to the metal-containing film 2003. More specifically, when the metal-containing film 2003 is a titanium nitride (TiN) film, a surface separation of TiN is about 2.1 Å and a surface separation of Si is about 1.9 Å, which is close to that of TiN. Therefore, the amorphous Si film 2002 is crystallized with being aligned to TiN. As a result, crystal lattices of the amorphous Si film 2002 are aligned in order from the amorphous Si film 2002 on the side of the metal-containing film 2003, such that the amorphous Si film 2002 may be crystallized. That is, by selectively heating the crystals of the metal-containing film 2003, which are action target grains, with the microwaves, the amorphous Si of the adjacent amorphous Si film 2002 is crystallized from the interface of the metal-containing film 2003. As a result, the amorphous Si film 2002 may be crystallized uniformly with a large crystal grain size within the film.

As described above, since the amorphous Si film 2002 is in contact with the metal-containing film 2003, when the metal-containing film 2003 generates the heat due to the microwave irradiation, the amorphous Si film 2002 is modified (crystallized) with a directionality from the side of the contact surface with the metal-containing film 2003, as indicated by an arrow in FIG. 6B. That is, the amorphous Si film 2002 is modified (crystallized) with the directionality from the amorphous Si film 2002 on the side of the metal-containing film 2003. Here, being crystallized with the directionality means that crystallization is performed in a direction away from the contact surface with the action target film.

Therefore, since the amorphous Si film 2002 may be modified into a crystalline Si film 2004 with the directionality from the amorphous Si film 2002 on the side of the contact surface with the metal-containing film 2003, the amorphous silicon film formed on the surface of the wafer 200 may be modified (crystallized) into a polysilicon film. Therefore, it is possible to uniformly modify the wafer 200.

As the action target film, the metal-containing film 2003 whose crystal lattice constant is the same as or close to the crystal lattice constant of the amorphous Si film 2002 which is the treatment target film may be used. As a result, a crystallization speed may be increased, thereby widening a crystallized region.

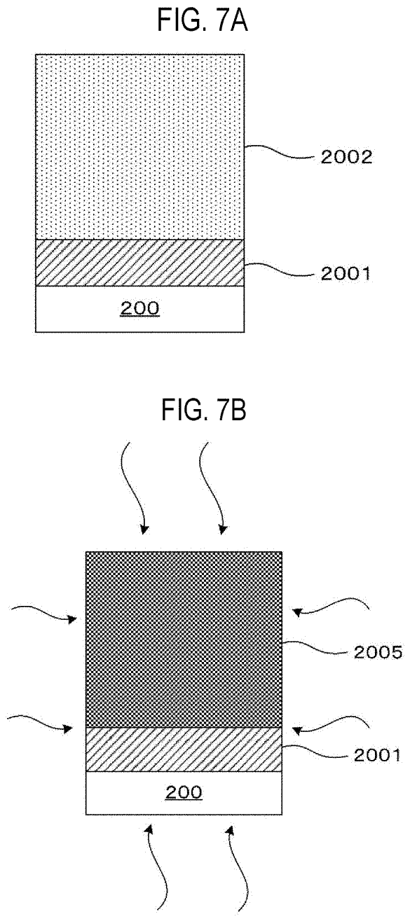

Here, as shown in FIG. 7A, when the wafer 200 formed thereon with the SiO film 2001 and the amorphous Si film 2002 is subjected to the modification treatment in this step, the amorphous Si film 2002 is randomly crystallized due to heat generation from the surroundings, as shown in in FIG. 7B.

Further, in thermal annealing treatment by resistance heating, the temperature may rise uniformly regardless of a type or a structure of a film formed on the wafer 200 due to radiation, convection, or transfer of heat from the heater. Further, when the amorphous silicon film is modified into the polysilicon film, since annealing treatment is performed at a heating temperature higher than the normal crystallization temperature, the temperature may be controlled by a method such as solid phase crystallization of aligning crystal planes or metal induced crystallization of controlling a grain size by lowering a crystal temperature. A temperature range in the method such as the solid phase crystallization or the metal induced crystallization is narrow because it is a mixed crystal temperature range for crystallization. Further, long-term thermal annealing treatment is performed for crystallization while suppressing variations in the crystal grain size.

In the present disclosure, the above-described problems may be solved by heating the metal-containing film 2003 provided to be in contact with the amorphous Si film 2002 by the microwaves. Further, since the amorphous Si film may be heated from the inside thereof, it is possible to increase the crystal grain size and uniformly modify (crystallize) the amorphous Si film from the amorphous Si film on the side of the metal-containing film 2003.

After a preset processing time elapses, the rotation of the boat 217, the supply of the gas, the supply of the microwaves, and the exhaust of the exhaust pipe are stopped.

### (Substrate Unloading Step (S505))

After the internal pressure of the process chamber 201 is returned to the atmospheric pressure, the gate valve 205 is opened such that the process chamber 201 is spatially in fluid communication with the transfer chamber 203. After that, the wafer 200 placed on the boat is unloaded to the transfer chamber 203 by the tweezers 125a of the transfer machine 125 (S505).

By repeating the above-described operations, the wafer 200 is modified and the process proceeds to the next substrate processing process.

As the next substrate processing process, for example, in a case where the above-mentioned metal-containing film (action target film or assist film) 2003 is useless due to the device characteristics, the metal-containing film may be removed. In a case where the action target film is useful due to the device characteristics, the action target film may not be removed.

In the present disclosure, a microwave absorption rate of the metal-containing film 2003 is larger than those of other films (for example, the SiO film 2001) on the wafer 200 excluding the wafer 200 and the amorphous Si film 2002, and the larger the difference thereof, the more thermal histories of other films (for example, the SiO film 2001) may be suppressed.

Although the above-described description is made by using the microwaves, since absorption characteristics of substance contained in the action target film (assist film) also depend on a wavelength of an electromagnetic wave, the present disclosure may use wavelengths of various electromagnetic waves other than the microwaves.

### Effects of the Embodiments of the Present Disclosure

According to the embodiments of the present disclosure, one or more effects set forth below may be obtained.

(a) By using the metal-containing film (action target film) 2003 and irradiating the metal-containing film 2003 with the microwaves when modifying (heat-treating) the amorphous Si film (treatment target film) 2002, it is possible to modify (crystallize) the amorphous Si film 2002 with the directionality.

Therefore, it is possible to uniformly modify (crystallize) the amorphous Si film from the amorphous Si film on the side of the metal-containing film 2003, making it possible to uniformly process the film formed on the substrate while lowering the temperature of the wafer 200.

(b) It is possible to selectively heat the metal-containing film (action target film) 2003, and since the amorphous Si film 2002 may be heated from the inside thereof, the crystal grain size may be increased.

(c) Since the metal-containing film (action target film) 2003 may be selectively heated, it is possible to raise a temperature in a region to be diffused. Further, the processing temperature may be shortened.

As described above, according to the present disclosure, it is possible to provide a technique of modifying a film formed on a substrate while lowering the temperature of the substrate.

Examples will be described below.

### First Example

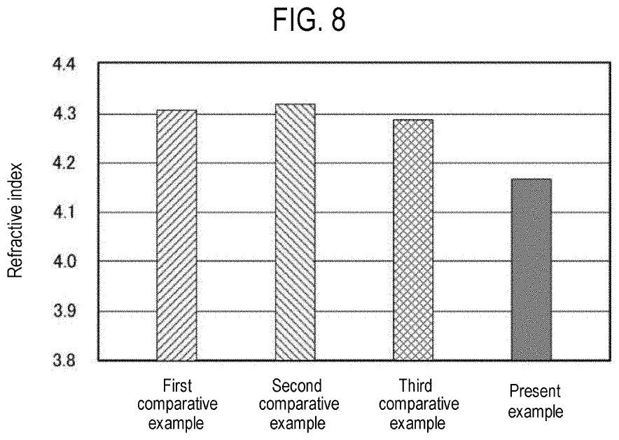

FIG. 8 is a diagram showing a comparison of a refractive index of an amorphous Si film in each of samples of first to third comparative examples and a refractive index of an amorphous Si film of a sample of the present example.

In FIG. 8, the first comparative example shows the refractive index of the amorphous Si film 2002 of the sample in which the SiO film 2001 and the amorphous Si film 2002 are formed on the wafer 200, as shown in FIG. 7A. That is, the first comparative example shows the refractive index of the amorphous Si film that is not subjected to the above-described modification treatment. The refractive index of the untreated amorphous Si film is about 4.3, indicating that the sample is amorphous.

The second comparative example shows the refractive index of the amorphous Si film of the sample shown in FIG. 7A after the sample is subjected to thermal annealing treatment at 600 degrees C. for 10 minutes. Here, the thermal annealing treatment means annealing treatment by resistance heating. The refractive index of the amorphous Si film after the thermal annealing treatment of the sample shown in FIG. 7A is a little more than about 4.3, indicating that the sample is amorphous.

The third comparative example shows the refractive index of the amorphous Si film of the sample shown in FIG. 7A after the sample is subjected to the above-described modification treatment by being irradiated with microwaves at 600 degrees C. for 10 minutes. The refractive index of the amorphous Si film of the sample shown in FIG. 7A after microwave irradiation is a little less than 4.3, indicating that the sample is insufficiently crystallized.

The present example shows the refractive index of the amorphous Si film of the sample shown in FIG. 6A after the sample is subjected to the above-described modification treatment by being irradiated with microwaves at 600 degrees C. for 10 minutes. The refractive index of the amorphous Si film of the sample shown in FIG. 6A after microwave irradiation is less than 4.2, indicating that the sample is crystallized. That is, it is confirmed that the amorphous Si film is modified into a crystalline Si film (polysilicon film or, crystal silicon film) with a crystal lattice.

That is, it is confirmed that the refractive index of the amorphous Si film is made smaller when the microwaves are used than when the microwaves are not used. Further, it is confirmed that the amorphous Si film is crystallized by heating the metal-containing film in contact with the amorphous Si film by the microwave irradiation. In other words, it is confirmed that the above-described action target film may be efficiently heated to crystallize the amorphous film by heating the above-described action target film by the microwave (electromagnetic wave) irradiation.

According to some embodiments of the present disclosure, it is possible to uniformly process a film formed on a substrate while lowering a temperature of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
loading a substrate in which a treatment target film and an action target film are formed into a process chamber;
irradiating the action target film with an electromagnetic wave; and
causing the action target film to generate heat by the irradiation with the electromagnetic wave and modifying the treatment target film with a directionality by heating the treatment target film with the heat generated by the action target film.

2. The method of claim 1, wherein the treatment target film and the action target film are provided to be in contact with each other, and
wherein the act of modifying includes crystallizing the treatment target film from a surface of the treatment target film where the treatment target film and the action target film are in contact with each other.

3. The method of claim 1, wherein the directionality causes the treatment target film to be crystallized in a direction away from a surface of the treatment target film where the treatment target film and the action target film are in contact with each other.

4. The method of claim 1, wherein the action target film is formed to cover a surface of the treatment target film.

5. The method of claim 1, wherein the treatment target film is a silicon-containing film.

6. The method of claim 5, wherein the action target film is a metal-containing film.

7. The method of claim 6, wherein in the act of modifying, the metal-containing film is caused to generate heat by the irradiation with the electromagnetic wave, and the silicon-containing film is crystallized by heating the silicon-containing film with the heat generated by the metal-containing film.

8. The method of claim 6, wherein the metal-containing film is a film containing at least one selected from the group of titanium and nickel.

9. The method of claim 2, wherein in the act of modifying, an atom-to-atom distance of the crystallized treatment target film approximates an atom-to-atom distance of the action target film by the heat generated by the action target film.

10. The method of claim 1, wherein the electromagnetic wave is microwaves.

11. The method of claim 1, further comprising removing the action target film.

12. The method of claim 11, wherein the act of removing is performed after the act of modifying.

13. The method of claim 1, wherein a crystal lattice constant of the action target film is the same as or approximates a crystal lattice constant of the treatment target film.

14. A method of manufacturing a semiconductor device, comprising the method of claim 1.

15. A non-transitory computer-readable recording medium recording a program that causes, by a computer, a substrate processing apparatus to perform a process comprising:
loading a substrate in which a treatment target film and an action target film are formed into a process chamber of the substrate processing apparatus;
irradiating the action target film with an electromagnetic wave; and
causing the action target film to generate heat by the irradiation with the electromagnetic wave and modifying the treatment target film with a directionality by heating the treatment target film with the heat generated by the action target film.

16. The non-transitory computer-readable recording medium of claim 15, wherein the electromagnetic wave is microwaves.

17. A substrate processing apparatus comprising:
a process chamber where a substrate in which a treatment target film and an action target film are formed is processed;
an electromagnetic wave oscillator configured to supply an electromagnetic wave into the process chamber; and
a controller configured to be capable of controlling the electromagnetic wave oscillator such that the action target film is caused to generate heat by irradiating the substrate with the electromagnetic wave and the treatment target film is modified with a directionality by heating the treatment target film with the heat generated by the action target film.

18. The substrate processing apparatus of claim 17, wherein the electromagnetic wave oscillator is a microwave oscillator.

19. The substrate processing apparatus of claim 17, wherein the electromagnetic wave oscillator is installed at a sidewall of the process chamber.
